(19) United States
(12) Patent Application Publication
(10) Pub. No.: US 2024/0337953 A1
(43) Pub. Date: Oct. 10, 2024

(54) SYSTEM AND METHOD FOR TRACKING REAL-TIME POSITION FOR SCANNING OVERLAY METROLOGY

(71) Applicant: KLA Corporation, Milpitas (CA)

(72) Inventors: Itay Gdor, Tel-Aviv (IL); Mordechy Kot, Migdal Haemek (IL); Yuval Lubashevsky, Haifa (IL); Nickolai Isakovitch, Tel-Aviv (IL); Daria Negri, Nesher (IL)

(21) Appl. No.: 18/372,531

(22) Filed: Sep. 25, 2023

Related U.S. Application Data
(60) Provisional application No. 63/457,137, filed on Apr. 4, 2023.

(51) Int. Cl. G03F 7/00

(52) U.S. Cl. CPC G03F 7/70633; G03F 7/706831; G03F 7/706837; G03F 7/706849; G03F 7/706851

(57) ABSTRACT

A method may include receiving time-varying interference signals from two or more photodetectors associated with a grating structure and a reference grating structure. The grating structure may include one or more diffraction gratings, where the reference grating structure includes a reference grating arranged next to the one or more diffraction gratings of the grating structure and where the one or more illumination beams simultaneously interact with grating structure and the reference grating structure as the sample is scanned relative to the illumination beam. The method may include determining at least one of a real-time position or a scanning velocity of the grating structure during the scan based on the reference grating signal. The method may include determining one or more overlay errors based on the grating signals from the grating structure and the real-time position of the grating structure during the scan determined based on the reference grating signal.

### CROSS-REFERENCE TO RELATED APPLICATIONS

The present applicant claims the benefit under 35 U.S.C. § 119 (e) of U.S. Provisional Application Ser. No. 63/457,137, filed on Apr. 4, 2023, which is incorporated herein by reference in the entirety.

### TECHNICAL FIELD

The present disclosure relates generally to overlay metrology and, more particularly, to scanning scatterometry overlay metrology.

### BACKGROUND

Overlay metrology generally refers to measurements of the relative alignment of layers on a sample such as, but not limited to, semiconductor devices. An overlay measurement, or a measurement of overlay error, typically refers to a measurement of the misalignment of fabricated features on two or more sample layers. In a general sense, proper alignment of fabricated features on multiple sample layers is necessary for proper functioning of the device.

Demands to decrease feature size and increase feature density are resulting in correspondingly increased demand for accurate and efficient overlay metrology systems. Metrology systems typically generate metrology data associated with a sample by measuring or otherwise inspecting overlay metrology targets distributed across the sample.

Overlay metrology targets are typically designed to provide diagnostic information regarding the alignment of multiple layers of a sample by characterizing an overlay target having target features located on sample layers of interest. Further, the overlay alignment of the multiple layers is typically determined by aggregating overlay measurements of multiple overlay targets at various locations across the sample. For example, the overlay metrology target may be scanned to provide overlay measurements value at the various locations across the sample.

During scanning, errors may originate from the stability of the scanning velocity. The position may used to improve accuracy and stability of the scanning measurement. Currently, the position is monitored using the encoder of the moving device (e.g., translator stage or mirror). The main disadvantage of using the encoder of the moving device is that it does not give the real-time position of the target. Rather it only provides the expected position because sample and the moving device are separated in space by the chuck (that holds the wafer) and the mount. As such, for example errors caused by chuck vibration will not be registered by the stage encoder.

Therefore, it is desirable to provide systems and methods for curing the above deficiencies.

### SUMMARY

An overlay metrology system is disclosed, in accordance with one or more embodiments of the present disclosure. In embodiments, the overlay metrology system includes an illumination sub-system. In embodiments, the illumination sub-system includes an illumination source configured to generate one or more illumination beams. In embodiments, the illumination sub-system includes one or more illumination optics configured to direct the one or more illumination beams to an overlay target on a sample as the sample is scanned relative to the one or more illumination beams along a scan direction when implementing a metrology recipe. In embodiments, the overlay target in accordance with the metrology recipe includes one or more cells having a grating structure and a reference grating structure. In embodiments, the grating structure includes one or more diffraction gratings, where the reference grating structure includes a reference grating arranged next to the one or more diffraction gratings of the grating structure, where the one or more illumination beams simultaneously interact with the grating structure and the reference grating structure as the sample is scanned relative to the one or more illumination beams, where the one or more diffraction gratings and the reference grating are periodic along the scan direction, where the reference grating has one or more known parameters. In embodiments, the overlay metrology system includes a collection sub-system. In embodiments, the collection sub-system includes two or more photodetectors located in a pupil plane to capture time-varying interference signals associated with diffraction orders of the grating structure and a time-varying interference signal associated with diffraction orders of the reference grating structure in the one or more cells when implementing the metrology recipe. In embodiments, the overlay metrology system includes a controller communicatively coupled to the two or more photodetectors. In embodiments, the controller includes one or more processors configured to execute program instructions. In embodiments, the program instructions are configured to cause the one or more processors to receive the time-varying interference signals from the two or more photodetectors, the time-varying interference signals including grating signals associated with the grating structures in the one or more cells as the overlay target is scanned in accordance with the metrology recipe and a reference grating signal associated with the reference grating structure in the one or more cells as the overlay target is scanned in accordance with the metrology recipe. In embodiments, the program instructions are configured to cause the one or more processors to determine at least one of a real-time position or a scanning velocity of the grating structure during the scan based on the reference grating signal from the reference grating. In embodiments, the program instructions are configured to cause the one or more processors to determine one or more overlay errors based on the grating signals from the grating structure and the at least one of the real-time position or the scanning velocity of grating structure during the scan determined based on the reference grating signal from the reference grating structure.

A method is disclosed, in accordance with one or more embodiments of the present disclosure. In embodiments, the method includes receiving time-varying interference signals from two or more photodetectors associated with a grating structure and a reference grating structure in one or more cells as an overlay target is scanned in accordance with a metrology recipe. In embodiments, the overlay target in accordance with the metrology recipe includes the one or more cells having the grating structure and the reference grating structure, where the grating structure includes one or more diffraction gratings, wherein the reference grating structure includes a reference grating arranged next to the one or more diffraction gratings of the grating structure, where the one or more illumination beams simultaneously interact with grating structure and the reference grating structure as the sample is scanned relative to the illumination beam, wherein the one or more diffraction gratings and the reference grating are periodic along the scan direction, where the reference grating has one or more known parameters. In embodiments, the time-varying interference signals include grating signals associated with the grating structures in the one or more cells as the overlay target is scanned in accordance with the metrology recipe and a reference grating signal associated with the reference grating structure in the one or more cells as the overlay target is scanned in accordance with the metrology recipe. In embodiments, the method includes determining at least one of a real-time position or a scanning velocity of the grating structure during the scan based on the reference grating signal from the reference grating. In embodiments, the method includes determining one or more overlay errors based on the grating signals from the grating structure and the real-time position of the grating structure during the scan determined based on the reference grating signal from the reference grating structure.

An overlay metrology target is disclosed, in accordance with one or more embodiments of the present disclosure. In embodiments, the overlay metrology target includes one or more cells having a grating structure and a reference grating structure. In embodiments, the grating structure includes one or more diffraction gratings. In embodiments, the reference grating structure includes a reference grating arranged adjacent to the one or more diffraction gratings of the grating structure. In embodiments, one or more illumination beams are configured to simultaneously interact with grating structure and the reference grating structure as a sample is scanned relative to the one or more illumination beams. In embodiments, the one or more diffraction gratings and the reference grating are periodic along the scan direction. In embodiments, the reference grating has one or more known parameters.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures in which:

FIG. 1A is a conceptual view of a system for performing scatterometry overlay metrology on overlay targets using pupil manipulations, in accordance with one or more embodiments of the present disclosure.

FIG. 1B is a schematic view of the overlay metrology tool, in accordance with one or more embodiments of the present disclosure.

FIG. 2A is a schematic view of a cell of an overlay target on a sample including a grating structure and a reference grating structure, in accordance with one or more embodiments of the present disclosure.

FIG. 2B is a schematic view of a cell of an overlay target on a sample including a grating structure and a reference grating structure, in accordance with one or more embodiments of the present disclosure.

FIG. 3A is a top view of an illumination pupil in an illumination pupil plane of the overlay metrology tool, in accordance with one or more embodiments of the present disclosure.

FIG. 3B is a top view of a collection pupil in the collection pupil plane of the overlay metrology tool including grating diffraction lobes associated with the illumination profile in FIG. 3A, in accordance with one or more embodiments of the present disclosure.

FIG. 4A is a schematic view of an illumination beam spot on the overlay target, in accordance with one or more embodiments of the present disclosure.

FIG. 4B is a plot depicting the illumination beam spot on the overlay target in FIG. 4A, in accordance with one or more embodiments of the present disclosure.

FIG. 4C is a plot depicting the illumination beam spot on the overlay target, in accordance with one or more embodiments of the present disclosure.

FIG. 5A is a schematic view of a plurality of illumination beam spots on the overlay target, in accordance with one or more embodiments of the present disclosure.

FIG. 5B is a plot depicting the plurality of illumination beam spots on the overlay target in FIG. 5A, in accordance with one or more embodiments of the present disclosure.

FIG. 5C is a plot depicting the plurality of illumination beam spots on the overlay target, in accordance with one or more embodiments of the present disclosure.

FIG. 6 is a flow diagram illustrating steps performed in a method for scanning overlay metrology of overlay targets, in accordance with one or more embodiments of the present disclosure.

FIG. 7A is a plot depicting constant scanning velocity, in accordance with one or more embodiments of the present disclosure.

FIG. 7B is a plot depicting inconstant scanning velocity, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to scanning scatterometry overlay using overlay targets including grating structures and a reference grating structures. For example, the grating structures may include one or more diffraction gratings, where the constituent gratings have different pitches and are not stacked on top of each other. For instance, at least one of the diffraction gratings may be printed in a side-by-side target (e.g., AIM target). By way of another example, the reference target may include a high frequency grating target that is arranged next to the overlay target. In this regard, the reference target may be used for direct, real-time position tracking, where the overlay target and the reference target may be scanned simultaneously.

For the purposes of the present disclosure, the term “scatterometry metrology” is used to broadly encompass the terms “scatterometry-based metrology” and “diffraction-based metrology” in which a sample having periodic features on one or more sample layers is illuminated with an illumination beam having a limited angular extent and one or more distinct diffraction orders are collected for the measurement. Further, the term “scanning metrology” is used to describe metrology measurements generated when a sample is in motion relative to illumination used for a measurement. In a general sense, scanning metrology may be implemented by moving the sample, the illumination, or both.

Embodiments of the present disclosure are directed to systems and methods for scanning overlay metrology based on time-varying interference signals from grating structures and a reference grating structure (e.g., clocking grating structure) in a collection pupil plane. It is contemplated herein that measurement conditions leading to diffraction orders of a grating structure and reference grating structure may lead to interference. Such interference signals may include information associated with asymmetries in the target structure such as, but not limited to, overlay between the top and bottom gratings, and the like. It is further contemplated herein that scanning the grating structure relative to an illumination beam (or vice versa) may provide characterization of the position-dependent overlay of the grating structure and may thus enable the determination of asymmetries such as, but not limited to overlay. Further, it is contemplated herein that by simultaneously scanning the grating structure and the reference grating structure (e.g., clocking grating structure), the reference grating structure may be used as a reference to measure and/or calibrate instabilities in scanning velocity, and the like. For example, the time-varying interference signals from the reference grating may be used to generate a real-time position and/or scanning velocity measurement of the sample during a scan such that any instabilities in the sample position and/or scanning velocity may be compensated for when providing an overlay measurement. It is contemplated herein that the time-varying interference signals from the reference grating may enable accurate overlay measurements in a wide range of measurement conditions, which may increase throughput. For example, requiring a constant scanning velocity during a measurement would require a relatively longer scan to allow a translation stage to achieve constant scanning velocity prior to reaching an overlay target of interest. In contrast, the use of time-varying interference signals from a reference grating on the sample captured simultaneously with time-varying interference signals from the grating structure removes this requirement and enables measurements when a translation stage is speeding up, slowing down, or otherwise not constant at the location of an overlay target of interest, which may substantially improve measurement throughput.

Some embodiments of the present disclosure are directed to scanning scatterometry overlay metrology based on time-varying interference signals associated with overlapping diffraction lobes from gratings (e.g., top or bottom gratings) of a grating structure or diffraction from the grating structure. For instance, scanning-based scatterometry measurement techniques may include fast detectors to capture time-varying interference signals generated as the sample is scanned. The detectors may be placed in the pupil plane at locations of overlap between selected diffraction orders to capture time-varying interference signals as the sample is scanned. Various non-limiting scanning scatterometry overlay metrology techniques are described in U.S. Pat. No. 11,300,405 issued on Apr. 12, 2022; U.S. Pat. No. 11,378,394, issued on Jul. 5, 2022; U.S. patent application Ser. No. 17/708,958, filed on Mar. 30, 2022; U.S. patent application Ser. No. 17/709,200, filed on Mar. 30, 2022; U.S. Patent Publication No. 2023/0213875, published on Jul. 6, 2023; U.S. patent application Ser. No. 18/099,798, filed on Jan. 20, 2023; U.S. patent application Ser. No. 18/110,746, filed on Feb. 16, 2023; and U.S. patent application Ser. No. 18/372,444, filed on Sep. 25, 2023, which are all incorporated herein by reference in their entireties. It is contemplated herein that the systems and methods of the above incorporated references may be extended or otherwise adapted to provide overlay measurements of grating structures.

In some embodiments, an overlay metrology system includes two or more photodetectors located in a pupil plane at positions corresponding to diffraction lobes from grating structures. For example, photodetectors may be located at locations of overlap between first-order diffraction lobes and one of 0-order diffraction lobes (e.g., specular reflection) or a portion of illumination split from the generated illumination beam (e.g., split into primary illumination and auxiliary illumination) prior to incidence. It is contemplated herein that these combined diffraction orders will exhibit time-varying interference signals (e.g., AC signals) during a scanning measurement, which may be captured using the two or more photodetectors. For example, the properties of the grating structures (e.g., pitches of the constituent gratings) and/or the measurement conditions (e.g., illumination wavelength, illumination incidence angle, collection angle, or the like) may be selected to provide that positive and negative diffraction orders associated with combined diffraction by the gratings of the grating structure are collected by the system and captured by the two or more photodetectors.

Some embodiments of the present disclosure are directed to providing recipes for configuring an overlay metrology tool. An overlay metrology tool is typically configurable according to a recipe including a set of parameters for controlling various aspects of an overlay measurement such as, but not limited to, the illumination of a sample, the collection of light from the sample, or the position of the sample during a measurement. In this way, the overlay metrology tool may be configured to provide a selected type of measurement for one or more overlay target designs of interest. For example, a metrology recipe may include illumination parameters such as, but not limited to, a number of illumination beams, an illumination wavelength, an illumination pupil distribution (e.g., a distribution of illumination angles and associated intensities of illumination at those angles), a polarization of incident illumination, or a spatial distribution of illumination. By way of another example, a metrology recipe may include collection parameters such as, but not limited to, a collection pupil distribution (e.g., a desired distribution of angular light from the sample to be used for a measurement and associated filtered intensities at those angles), collection field stop settings to select portions of the sample of interest, polarization of collected light, wavelength filters, positions of one or more detectors (e.g., photodetectors) or parameters for controlling the one or more detectors. By way of a further example, a metrology recipe may include various parameters associated with the sample position during a measurement such as, but not limited to, a sample height, a sample orientation, whether a sample is static during a measurement, or whether a sample is in motion during a measurement (along with associated parameters describing the speed, scan pattern, or the like).

In some embodiments, the properties of the grating structures (e.g., pitches of the constituent gratings, or the like) and the measurement conditions (e.g., illumination wavelength, illumination incidence angle, collection angle, or the like) are arranged or otherwise selected (e.g., using a metrology recipe) to provide a selected distribution of diffraction and/or combined diffraction orders and to further provide that two or more photodetectors are placed at suitable locations to capture these diffraction orders to generate time-varying interference signals of interest.

It is further contemplated herein that the systems and methods disclosed herein may provide sensitive overlay metrology at a high throughput. For example, the non-imaging configuration enables the use of fast photodetectors suitable for fast scan speeds. As a non-limiting example, photodetectors having a bandwidth of 1 GHz may enable scan speeds of approximately 10 centimeters per second on targets having a pitch of 1 micrometer.

The grating structures may generally be formed as portions of overlay targets and may generally be located anywhere on the sample. Further, overlay targets may include one or more measurement cells, where each cell includes printed elements in non-overlapping regions of one or more layers on the sample to form the grating structures. An overlay measurement may then be based on any combination of measurements of the various cells of the overlay target.

It is contemplated herein that scatterometry overlay metrology using a reference grating as disclosed herein may provide numerous benefits. For example, the system and method disclosed herein may utilize overlay targets including non-stacked gratings. By way of another example, overlay measurements between two or more layers may be determined in a single metrology measurement, where one or more layers of the metrology target are not stacked. In one instance, pupil manipulations may enable measuring multi-layer overlay in a single scan. In another instance, pupil manipulations may enable overlay targets (e.g., Moiré, AIM, etc.) where printing different pitches stacked on top of each other is not allowed due to design rules. By way of another example, the system and method disclosed herein may overcome difficulties in measuring each layer in its ideal condition since the laser scanning method performance is not strongly dependent on the wavelength of light used.

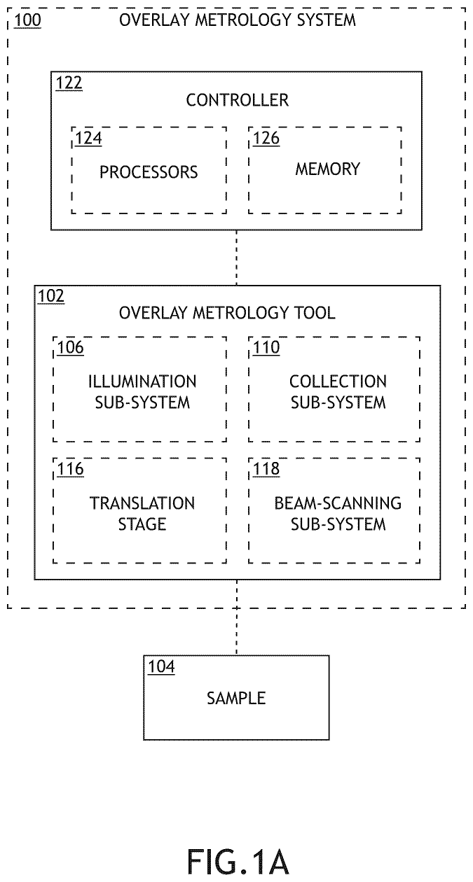

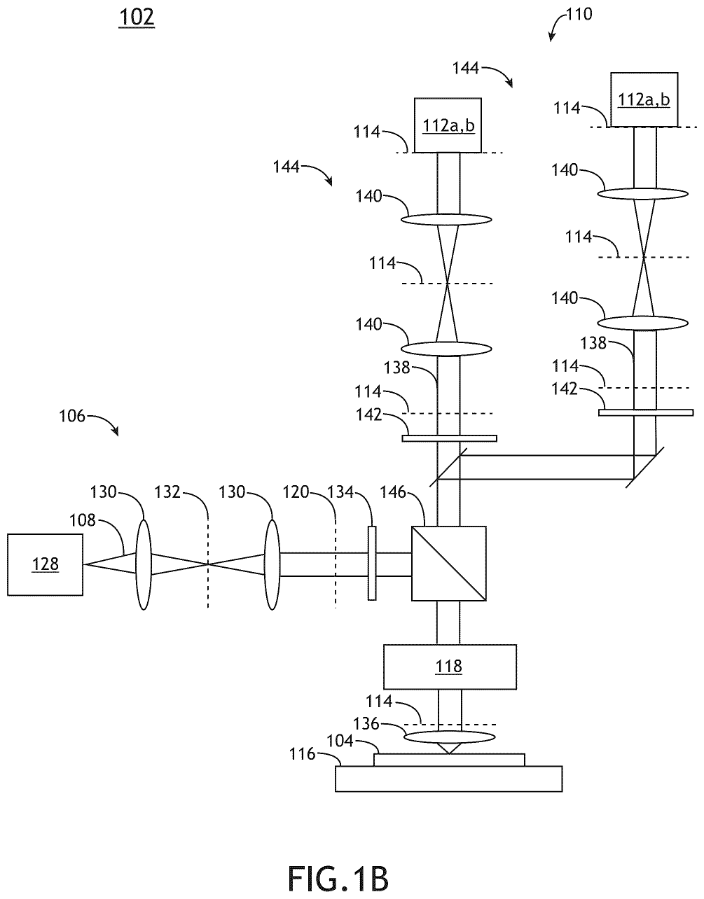

Referring now to FIGS. 1A-7B, systems and methods for tracking real-time position for scanning overlay metrology, are described in greater detail in accordance with one or more embodiments of the present disclosure.

FIG. 1A is a conceptual view of an overlay metrology system 100 for performing scatterometry overlay metrology on a multi-overlay stack grating metrology target, in accordance with one or more embodiments of the present disclosure.

In embodiments, the overlay metrology system 100 includes an overlay metrology tool 102 to perform scatterometry overlay measurements of a sample 104. For example, the overlay metrology tool 102 may perform scatterometry overlay measurements on portions of the sample 104 having grating structures.

FIG. 1B is a schematic view of the overlay metrology tool 102, in accordance with one or more embodiments of the present disclosure.

In embodiments, the overlay metrology tool 102 includes an illumination sub-system 106 to generate illumination in the form of one or more illumination beams 108 to illuminate the sample 104 and a collection sub-system 110 to collect light from the illuminated sample 104. For example, the one or more illumination beams 108 may be angularly limited on the sample 104 such that grating structures (e.g., in one or more cells of an overlay target) may generate discrete diffraction orders. Further, the one or more illumination beams 108 may be spatially limited such that they may illuminate selected portions of the sample 104. For instance, each of the one or more illumination beams 108 may be spatially limited to illuminate a particular cell of an overlay target. In some embodiments, the one or more illumination beams 108 underfill a particular cell of an overlay target.

The collection sub-system 110 may then collect at least some diffraction orders associated with diffraction of the illumination beam 108 from a grating structure. Further, the collection sub-system 110 may include at least two photodetectors 112 positioned in a collection pupil plane 114 at locations associated with time-varying interference signals indicative of overlay. For example, as will be described in greater detail below, suitable locations for the two or more photodetectors 112 may include, but are not limited to, locations associated with positive and negative diffraction orders or locations associated with overlap between diffraction orders of the constituent gratings of a grating structure (e.g., an overlap region between +1 diffraction orders of gratings or an overlap region between −1 diffraction orders of the gratings and the zero order diffraction).

In embodiments, the overlay metrology tool 102 includes a translation stage 116 to scan the sample 104 through a measurement field of view of the overlay metrology tool 102 during a measurement to implement scanning metrology.

In embodiments, the overlay metrology tool 102 includes a beam-scanning sub-system 118 configured to modify or otherwise control a position of at least one illumination beam 108 on the sample 104. For example, the beam-scanning sub-system 118 may scan an illumination beam 108 in a direction along a scan direction (e.g., a direction in which the translation stage 116 scans the sample 104) during a measurement.

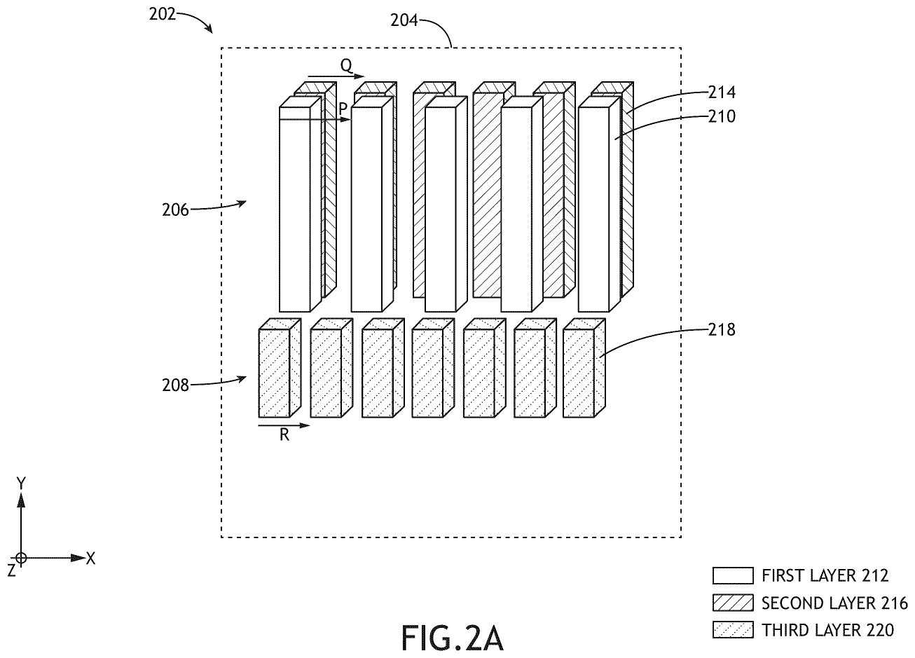

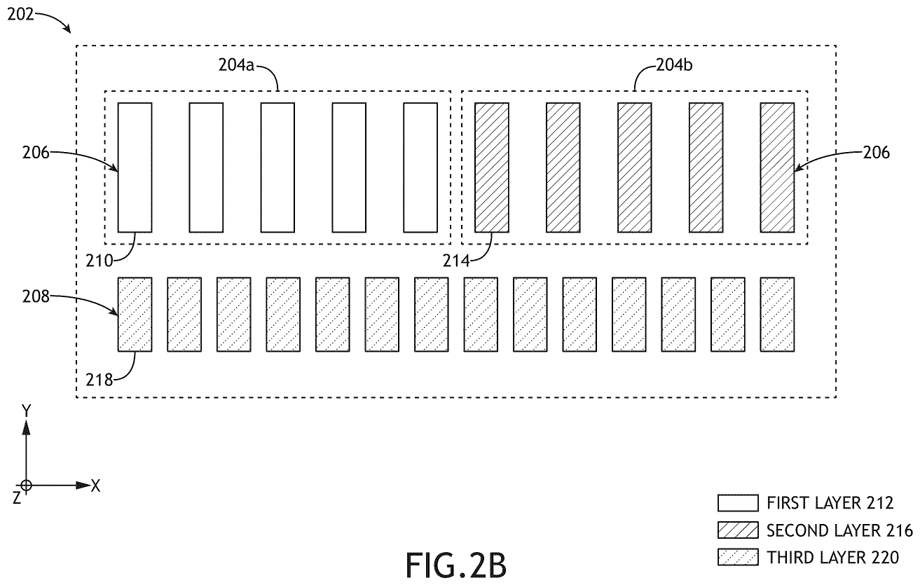

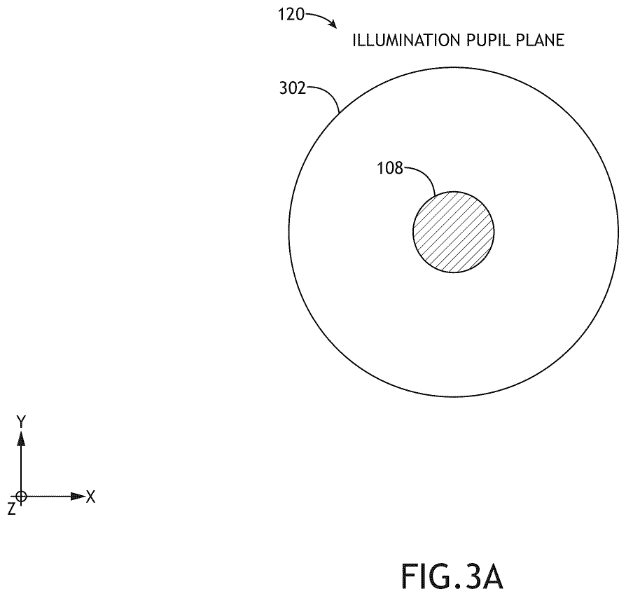

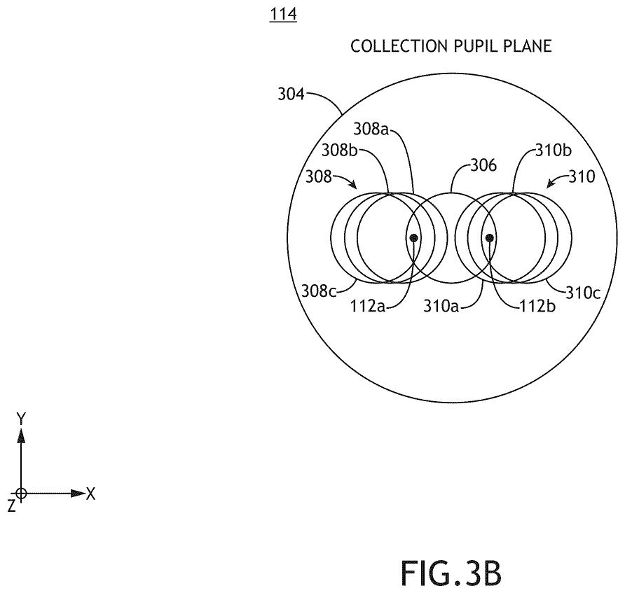

Referring now to FIGS. 2A-3B, the collection of diffraction orders from grating structures and the placement of the two or more photodetectors 112 for scanning scatterometry overlay metrology is described in greater detail, in accordance with one or more embodiments of the present disclosure.

FIGS. 2A-2B are schematic views of one or more cells 202, in accordance with one or more embodiments of the present disclosure.

In embodiments, the overlay target 204 includes one or more cells 202, where any particular cell 202 of the one or more cells 202 may include a grating structure 206 with a periodicity along any direction and a reference grating structure 208 with a periodicity along a similar direction. For example, as shown in FIG. 2A, the overlay target 204 may include a single cell 202 with a grating structure 206 and a reference grating structure 208 having periodicity along a common direction. By way of another example, as shown in FIG. 2B, the overlay target 204 may include a plurality of cells 202a,b, where the different cells 202a,b have different configurations of the periodicities of the associated gratings. For instance, as shown in FIG. 2B, the overlay target 204 may include a plurality of cells 202a,b and each cell 202a,b includes a grating structure 206 having periodicity along a common direction and a reference grating 208 having a periodicity along the common direction, where the different cells 202a,b have different configurations of the periodicities of the associated gratings.

In embodiments, as shown in FIG. 2A, the grating structure 206 includes two or more diffraction gratings. For example, the grating structure 206 may include a first exposure structure 210 located on a first layer 212 of the sample 104 and second exposure structure 214 located on a second layer 216 of the sample 104. For instance, the grating structure 206 may include a grating-over-grating structure, where first exposure structure 210 and the second exposure structure 214 are overlapping.

In embodiments, as shown in FIG. 2B, the grating structure 206 includes one or more diffraction gratings. For example, the grating structure 206 may include a first exposure structure 210 located on a first layer 212 of the sample 104 and a second exposure structure 214 located on a second layer 216 of the sample 104, where the first exposure structure 210 and the second exposure structure 214 are arranged along the scan direction. For instance, the second exposure structure 214 may be arranged adjacent to the first exposure structure 210, such that the first exposure structure 210 does not overlap with the second exposure structure 214. It is contemplated that the first exposure structure 210 may be associated with a first lithographic exposure and the second exposure structure 214 may be associated with a second lithographic exposure, where the first and second lithographic exposure may be on the same layer or different layers (as shown in FIGS. 2A-2B).

In embodiments, the first exposure structure 210 and the second exposure structure 214 may have different pitches. For example, FIG. 2A illustrates the pitches of the first exposure structure 210 and the second exposure structure 214 as P and Q, respectively. It is noted that the configuration depicted in FIG. 2A is provided merely for illustrative purposes and shall not be construed as limiting the scope of the present disclosure. As such, the grating structure 206 may be formed of any number of layers with any variety of pitches. For example, the grating structure 206 may be formed of two or more layers.

In embodiments, the first exposure structure 210 and the second exposure structure 214 may have identical pitches. For example, as shown in FIG. 2B, the first exposure structure 210 and the second exposure structure 214 may have identical pitches. It is contemplated that where the grating structures 206 has identical pitches, the tool-induced-shift (TIS) errors may be reduced (as shown in FIG. 2B for example).

In embodiments, the reference grating structure 208 includes a reference grating 218. For example, the reference grating 218 may be located on a third layer 220 of the sample. Although FIGS. 2A-2B depict the reference grating 218 on the third layer 220, it is contemplated that the reference grating 218 may be arranged any either the first or second layer, rather FIGS. 2A-2B are provided merely for illustrative purposes.

It is contemplated herein that the reference grating structure 208 may be in the same cell or a different cell than the grating structure 206.

The frequency (or pitch) of the reference grating 218 may be different from the frequency (or pitch) of gratings 210, 214 of the grating structure 206. For example, the frequency of the reference grating 218 may be greater than the frequency of gratings 210, 214 of the grating structure 206. Put another way, the pitch of the reference grating 218 may be smaller than the pitch of gratings 210, 214 of the grating structure 206. For instance, as noted above in FIG. 2A, the pitches of the first exposure structure 210 and the second exposure structure 214 may be P and Q, respectively, and the pitch of the reference grating 218 may be R.

The reference grating 218 may have one or more known parameters. For example, the frequency of the reference grating 218 may be known. In this regard, the frequency of the reference grating 218 may be monitored to determine one of a real-time position or scanning velocity, such that variations in the scanning velocity may be corrected.

In embodiments, the reference grating structure 206 is arranged next to the grating structure 206 (e.g., in a non-overlapping arrangement). For example, the reference grating 218 may be arranged next to the first exposure structure 210 of the grating structure 206 and the second exposure structure 214 of the grating structure 206. In one instance, as shown in FIG. 2A, the reference grating 218 may be arranged between the overlapping first exposure structure 210 and second exposure structure 214 of the grating structure 206. In another instance, as shown in FIG. 2B, the reference grating 218 may be arranged below the first exposures structure 210 of the grating structure 208 and the second exposure structure 214 of the grating structure 206. In this regard, as will be discussed further herein, as the overlay target 204 is scanned by the illumination beam, the illumination beam may simultaneously interact with the grating structure 206 and the reference structure 206.

It is to be understood, however, that the overlay target 204 in FIGS. 2A-2B and the associated description are provided solely for illustrative purposes and should not be interpreted as limiting. Rather, the overlay target 204 may include any suitable grating overlay target design. For example, the overlay target 204 may include any number of cells 202 suitable for measurement. Further, the cells 202 may be distributed in any pattern or arrangement. In embodiments, the overlay target 204 includes one or more cell groupings distributed along a scanning direction (e.g., a direction of motion of the sample 104), where cells 202 within each particular cell grouping are oriented to have grating structures 206 periodically along a common direction.

Referring now to FIGS. 3A-3B, various non-limiting configurations for the generation and measurement of time-varying interference signals from a grating structure 206 and a reference grating structure 208 in a cell 202 of an overlay target 204 are described in accordance with one or more embodiments of the present disclosure.

FIG. 3A is a top view of an illumination pupil 302 in an illumination pupil plane 120 of the overlay metrology tool 102, in accordance with one or more embodiments of the present disclosure. For example, the illumination pupil plane 120 may correspond to a pupil plane in the illumination sub-system 106 as illustrated in FIG. 1B. In embodiments, the illumination sub-system 106 illuminates the overlay target 204 with one or more illumination beams 108 at normal incidence (or near-normal incidence) as illustrated in FIG. 3A. In this regard, the overlay target 204 may diffract the one or more illumination beams 108 into discrete diffraction orders.

FIG. 3B illustrates a non-limiting configuration of diffraction orders of the illumination beam 108, associated with the overlay metrology target 204 shown in FIG. 2A, in a collection pupil plane 114 and associated positions of the two or more photodetectors 112 suitable for capturing time-varying interference signals from which an overlay measurement may be extracted. It is contemplated herein that the two or more photodetectors 112 placed at locations in the collection pupil plane 114 associated with diffraction lobes may capture time-varying interference signals indicative of overlay. It is further contemplated herein that time-varying interference signals associated with combined diffraction lobes may be captured by a photodetector 112 when each of the relevant diffraction lobes are incident on the photodetector 112 (e.g., are within a measurement area of the photodetector 112). In this way, the relevant diffraction lobes need not necessarily overlap in the collection pupil plane 114 but rather may overlap on the photodetector 112.

It is recognized herein that the distribution of diffracted orders of an illumination beam 108 by a periodic structure, such as a grating structure 206 or reference grating structure 208, may be influenced by a variety of parameters such as, but not limited to, a wavelength of the illumination beam 108, an incidence angle of the illumination beam 108 in both altitude and azimuth directions, pitches of the gratings of the grating structure 206, or a numerical aperture (NA) of a collection lens. Accordingly, in embodiments of the present disclosure, the illumination sub-system 106, the collection sub-system 110, and the overlay target 204 may be configured (e.g., according to a metrology recipe defining a selected set of associated parameters) to provide a desired distribution of diffraction orders in a collection pupil plane 114 suitable for generating time-varying interference patterns indicative of overlay. For example, the illumination sub-system 106 and/or the collection sub-system 110 may be configured to generate measurements on grating structures having selected range periodicities to provide a desired distribution in the collection pupil plane 114. Further, various components of the illumination sub-system 106 and/or the collection sub-system 110 (e.g., stops, pupils, or the like) may be adjustable to provide the desired distribution in the collection pupil plane 114.

In embodiments, the collection pupil plane 114 may correspond to a pupil plane in the collection sub-system 110 as illustrated in FIG. 1B. For example, FIG. 3B depicts, for each grating of the overlay target 204 shown in FIG. 2A, the 0-order diffraction 306, −1 order grating diffraction 308, and +1 order grating diffraction 310 distributed along the direction of periodicity of the grating structure 206 (e.g., the X direction here) in the collection pupil plane 114. For instance, the −1 order grating diffraction 308a and the +1 order grating diffraction 310a may be associated with grating diffraction from first exposure structure 208, the −1 order grating diffraction 308b and the +1 order grating diffraction 310b may be associated with grating diffraction from the second exposure structure 214, and the −1 order grating diffraction 308c and the +1 order grating diffraction 310c may be associated with grating diffraction from reference grating 218, where the diffraction angles are based on a pitch of the gratings and illumination wavelength. In this regard, the respective diffraction lobes of the +1 order grating diffraction 308a-c from the respective layers 210, 214, 218 may overlap and the −1 order grating diffraction 310a-c from the respective layers 210, 214, 218 may overlap.

It is contemplated herein that the phase of each of the grating diffraction orders (e.g., the −1 order grating diffraction 308 and the +1 order grating diffraction 310) may oscillate during a scan to form time-varying interference signals and overlay may be determined based on these oscillations phases. As a result, an overlay measurement may be performed by capturing and comparing these time-varying interference patterns. For example, the phase differences of the −1 order and +1 order grating diffraction 308, 310 from each individual grating may be used to measure the position of the grating relative to the optical system.

It is to be understood, however, that the particular configuration illustrated in FIG. 3B and the associated description is not limiting. In particular, it is contemplated herein that the time-varying interference signals may be captured using various metrology overlay techniques, as generally discussed in U.S. Pat. No. 11,300,405 issued on Apr. 12, 2022; U.S. Pat. No. 11,378,394, issued on Jul. 5, 2022; U.S. patent application Ser. No. 17/708,958, filed on Mar. 30, 2022; U.S. patent application Ser. No. 17/709,200, filed on Mar. 30, 2022; U.S. Patent Publication No. 2023/0213875, published on Jul. 6, 2023; U.S. patent application Ser. No. 18/099,798, filed on Jan. 20, 2023; and U.S. patent application Ser. No. 18/110,746, filed on Feb. 16, 2023, which are each incorporated by reference in their entirety.

For example, Moiré diffraction lobes may overlap with 0-order diffraction in the collection pupil plane (e.g., as provided by a metrology recipe). In this example, a first photodetector may be located at a region of overlap between the −1 order Moiré diffraction and the 0-order diffraction and a second photodetector may be located at a region of overlap between the +1 order Moiré diffraction and the 0-order diffraction, where each of the photodetectors 112 may then capture a time-varying interference signal as the sample 104 is scanned. Additionally, an overlay measurement may be determined based on time-varying signals associated with only the first-order Moiré diffraction lobes (e.g., without reference to 0-order diffraction). By way of another example, the first-order diffraction from the first exposure structure 210 and the second exposure structure 214 overlap in the collection pupil 304. For instance, a first photodetector may be located in a first overlap region between −1 order diffraction from the first exposure structure 210 (−1_{TOP}) and −1 order diffraction from the second exposure structure 214 (−1_{BOTTOM}), and a second photodetector may be located in a second overlap region between +1 order diffraction from the first exposure structure 210 (+1_{TOP}) and +1 order diffraction from the second exposure structure 214 (+1_{BOTTOM}). By way of another example, an overlay measurement may be determined based on time-varying signals associated with the first-order grating diffraction lobes (e.g., without reference to 0-order diffraction 306) and second-order diffraction lobes. Further, the first-order diffraction lobes need not necessarily overlap in the collection pupil plane, but may overlap on the respective photodetectors 112a,b in some embodiments. Additionally, in some embodiments, an overlay measurement is determined based on time-varying signals associated with only the first-order grating diffraction lobes (e.g., without reference to 0-order diffraction 306). For example, an overlay measurement may be determined based on time-varying signals associated with overlap between auxiliary illumination (e.g., illumination split from the generated illumination beam) and first order diffraction lobes, as generally discussed in U.S. patent application Ser. No. 18/110,746, filed on Feb. 16, 2023, which is incorporated herein by reference in the entirety.

It is further contemplated the 0-order diffraction 306 need not necessarily overlap with the −1 order grating diffraction 308 and the +1 order grating diffraction 310 in the collection pupil 304 as illustrated in FIG. 3B. Rather, in some embodiments, these diffraction lobes are sufficiently close together that the 0-order diffraction 306 overlaps with the −1 order grating diffraction 308 on a first photodetector 112a and the 0-order diffraction 306 overlaps with the +1 order grating diffraction 310 on a second photodetector 112b.

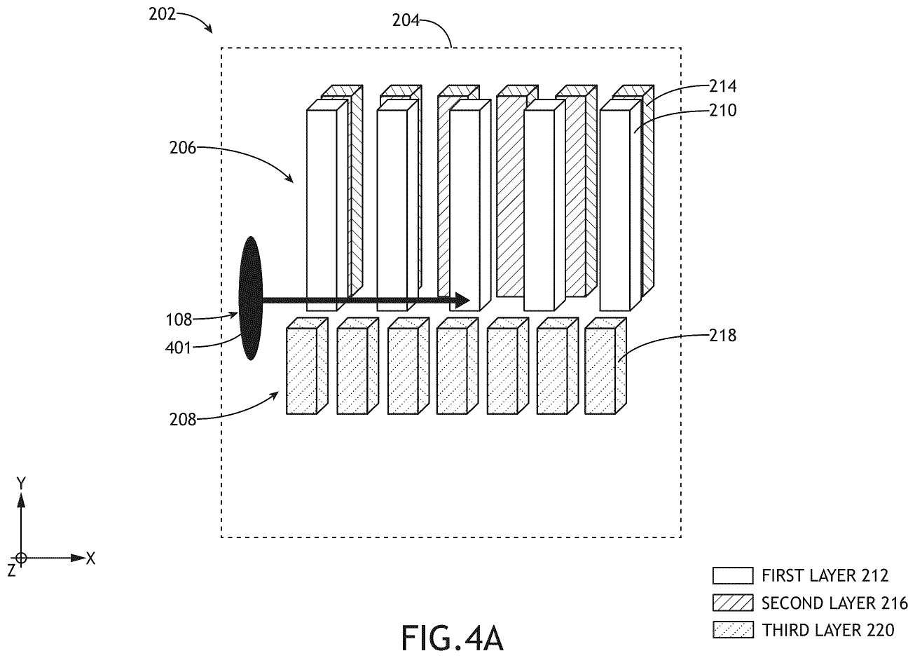

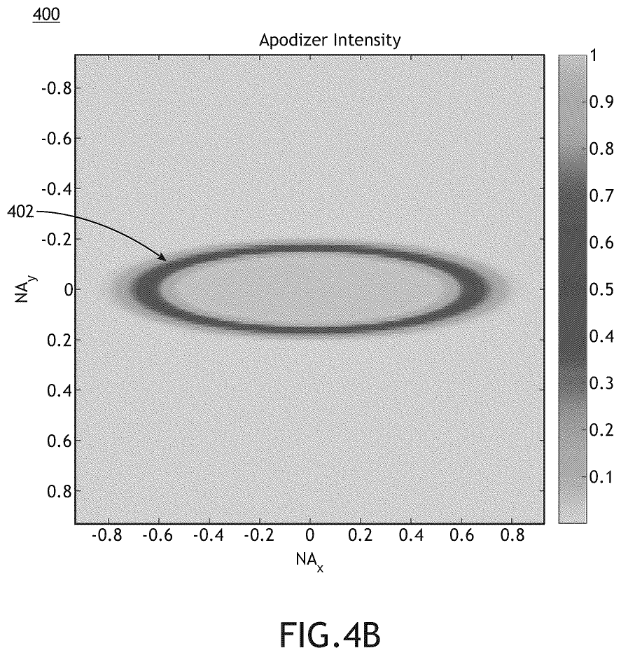

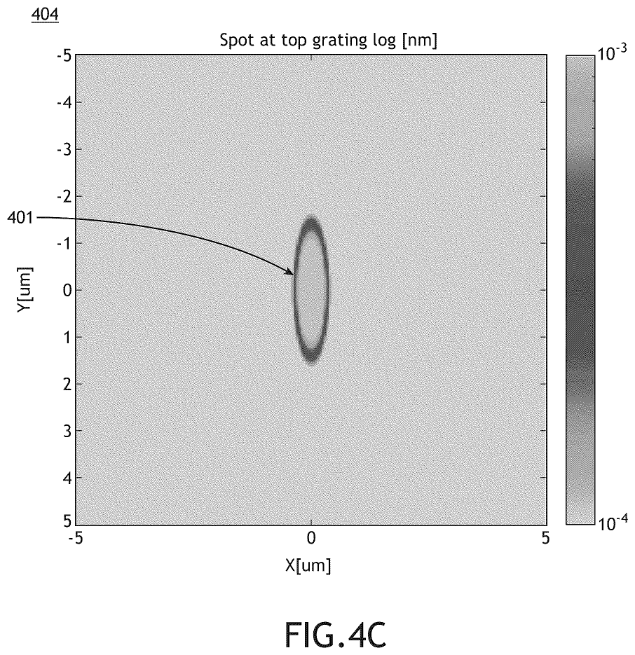

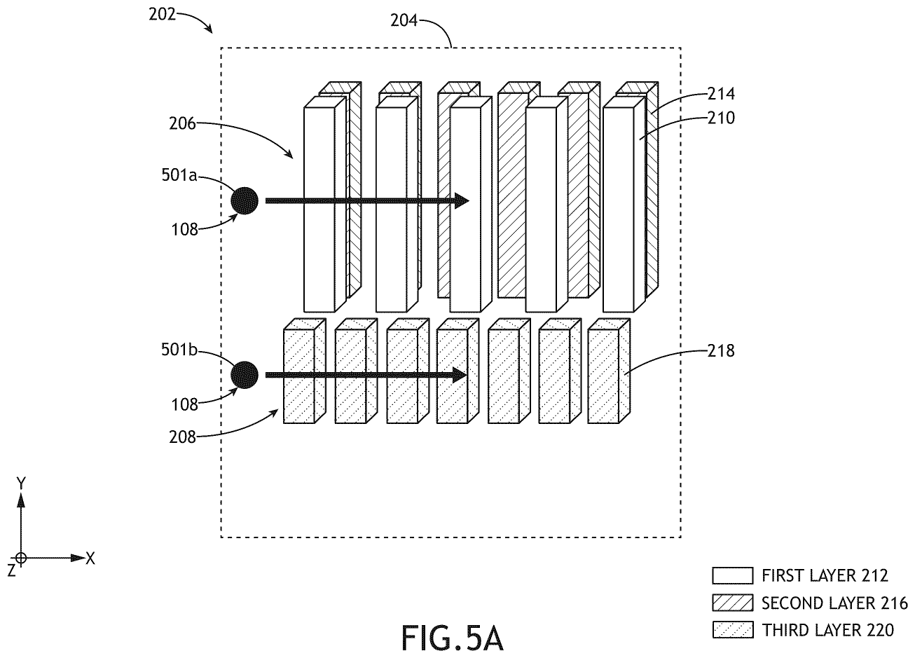

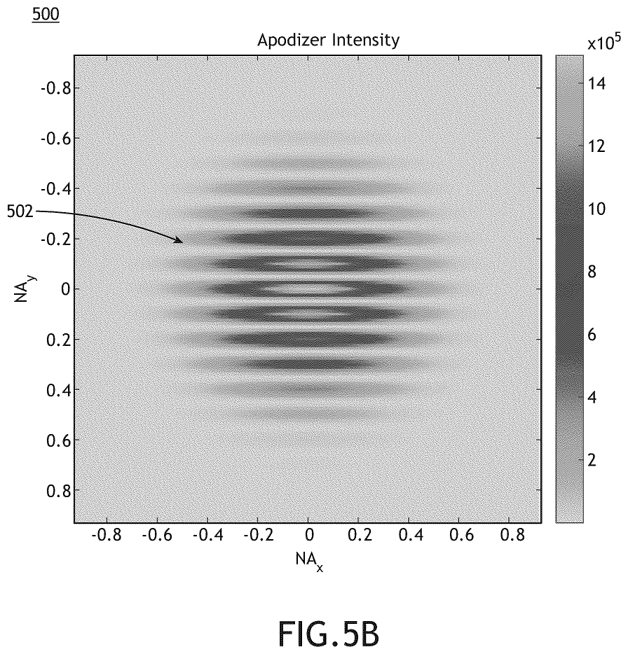

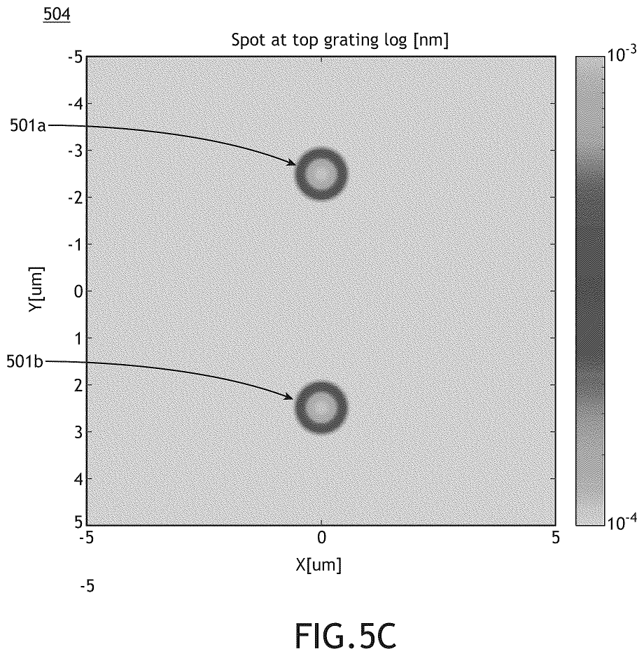

Referring generally to FIGS. 4A-5C, in embodiments, the one or more illumination beams 108 of the illumination sub-system 106 simultaneously interact with both the grating structure 206 and the reference grating structure 208. For example, as the overlay metrology target 204 is scanned by the one or more illumination beams 108, the one or more illumination beams 108 interact with the gratings of the grating structure 206 (e.g., first exposure structure 210 and second exposure structure 214) and the reference grating 218 of the reference grating structure 208. In this regard, the reference grating structure 208 may be used a reference to directly calibrate the time-varying interference signals from the grating structure 206 based on observations derived from the time-varying interference signals from the reference grating structure 208 (e.g., position or velocity of the reference beam).

Simultaneous interaction of the illumination beams is generally discussed in U.S. patent application Ser. No. 18/372,444, filed on Sep. 25, 2023, which is incorporated herein by reference in the entirety.

FIG. 4A is a schematic view of a cell 202 of an overlay metrology target 204 being scanned with an illumination beam 108, in accordance with one or more embodiments of the present disclosure. FIG. 4B is a graph 400 depicting an apodizer function 402 used to generate the illumination beam 108 in FIG. 4A, in accordance with one or more embodiments of the present disclosure. FIG. 4C is a graph 404 depicting a simulated illumination spot 401 generated using the apodizer function 402 in FIG. 4B, in accordance with one or more embodiments of the present disclosure.

Referring generally to FIGS. 4A-4C, in embodiments, the one or more illumination beams 108 are elongated orthogonally in the scan direction. For example, the one or more illumination beams 108 may be elongated orthogonally in the scan direction such the grating structure 206 and the reference grating structure 208 are scanned simultaneously.

Referring to FIGS. 4B-4C, in embodiments, one or more optical elements 134 of the illumination sub-system 106 may be used to modify the one or more illumination beams 108. For example, an apodizer function 402 in the illumination pupil field may be used to generate an elongated illumination beam 401. For instance, the apodization function 402 in the pupil field shown in FIG. 4B may be used to generate the elongated illumination beam 401. In this regard, as shown in FIG. 4A, the elongated illumination beam 401 may interact with the first exposure structure 210 and the second exposure structure 214 of the grating structure 208 and the reference grating 218 of the reference grating structure 208 as the overlay target 204 is scanned.

FIG. 5A is a schematic view of a cell 202 of an overlay metrology target 204 being scanned with two illumination beams 108, in accordance with one or more embodiments of the present disclosure. FIG. 5B is a graph 500 depicting an apodizer function 502 used to generate the separated illumination beams 108 in FIG. 5A, in accordance with one or more embodiments of the present disclosure. FIG. 5C is a graph 504 depicting separated simulated illumination spots 501a,b generated using the apodizer function 502 in FIG. 5B, in accordance with one or more embodiments of the present disclosure.

Referring generally to FIGS. 5A-5C, in embodiments, the one or more illumination beams 108 are separated to generate two separate illumination beams 501a, 501b in the pupil field. For example, the one or more illumination beams 108 may be separated to generate two separate illumination beams 501a, 501b. For instance, a first illumination beam 501a may interact with the grating structure 206 and a second illumination beam 501b may interact with the reference grating structure 208.

In embodiments, one or more optical elements 134 of the illumination sub-system 134 (e.g., apodizers) may be used to generate the separated illumination beams 501a, 501b by separating the one or more illumination beams 108. For example, an apodizer function 502 in the pupil field may be used to generate the separated illumination beams 501a, 501b. For instance, the apodization spot 502 in the pupil field shown in FIG. 5B may be used to generate the separated illumination beams 501a, 501b, such that the separated illumination beams 501a,b are mutually coherent (e.g., phases of the associated time-varying interference signals are synchronized). In this regard, as shown in FIG. 5A, the separated illumination beams 501a, 501b may simultaneously interact with the first exposure structure 210 and the second exposure structure 214 of the grating structure 208 and the reference grating 216 of the reference grating structure 208 as the overlay target 204 is scanned.

Although FIGS. 5A-5C depict two spots, it is noted that FIGS. 5A-5C are provided merely for illustrative purposes and shall not be construed as the limiting the scope of the present disclosure. For example, the system and method of the present disclosure may be used to measure three or more side-by-side gratings.

Further, it is contemplated herein that any optical element and/or illumination source may be used to generate one of an elongated beam or separated illumination beams, therefore FIGS. 4A-5C are provided merely for illustrative purposes and shall not be construed as limiting the scope of the present disclosure.

Referring again to FIG. 1A, additional components of the overlay metrology tool 102 are described in greater detail in accordance with one or more embodiments of the present disclosure.

In embodiments, the overlay metrology system 100 includes a controller 122 communicatively coupled to the overlay metrology tool 102. The controller 122 may include one or more processors 124 and a memory device 126, or memory. For example, the one or more processors 124 may be configured to execute a set of program instructions maintained in the memory device 126.

In embodiments, the controller 122 may execute any of various processing steps associated with overlay metrology. For example, the controller 122 may be configured to generate control signals to direct or otherwise control the overlay metrology tool 102, or any components thereof. For instance, the controller 122 may be configured to direct the translation stage 116 to translate the sample 104 along one or more measurement paths, or swaths, to scan one or more overlay targets through a measurement field of view of the overlay metrology tool 102 and/or direct the beam-scanning sub-system 118 to position or scan one or more modified illumination beams on the sample 104. By way of another example, the controller 122 may be configured to receive signals corresponding to the time-varying interference signals from the photodetectors 112. By way of another example, the controller 122 may generate correctables for one or more additional fabrication tools as feedback and/or feed-forward control of the one or more additional fabrication tools based on overlay measurements from the overlay metrology tool 102.

In embodiments, the controller 122 captures the interference signals detected by the photodetectors 112. For example, the controller 122 may generally capture data such as, but not limited to, the magnitudes or the phases of the time-varying interference signals using any technique known in the art such as, but not limited to, frequency-domain analysis (e.g., FFT), one or more phase-locked loops, and the like. Further, the controller 122 may capture the interference signals, or any data associated with the interference signals, using any combination of hardware (e.g., circuitry) or software techniques.

In embodiments, the controller 122 separates the interference signals detected by the photodetectors 112. For example, the interference signals associated with the reference grating structure 208 may be separated from the interference signals associated with the grating structure 206. In one instance, the controller 122 may be configured to separate the respective interference signals using Fourier transform. In another instance, the controller 122 may be configured to separate the respective interference signals using model fitting.

In some embodiments, the interference signals associated with the reference grating structure 208 are spatially separated from the interference signals associated with the grating structure 206. For example, the spatially separated signals may be read using a dedicated diode in the field. In this regard, the controller 122 may receive the spatially separated signals, such that the controller 122 may determine a real-time position or scanning velocity.

In embodiments, the controller 122 determines one of a real-time position or a scanning velocity of one of the sample or the grating structure during a scan based on the reference grating signal from the reference grating. For example, in a non-limiting example, the controller 122 may be configured to determine the reference time-varying interference signal based on the separated time-varying interference signals. By way of another example, in a non-limited example, the controller 122 may be configured to receive the reference time-varying interference signal from the dedicated diode.

In embodiments, the reference time-varying interference signal may be used as the real-time position or scanning velocity. For example, the reference grating time-varying interference signal may be used to analyze the grating time-varying interference signals from the grating structure 206. In this regard, the reference grating time-varying interference signal may be used as a feedback or feedforward loop to adjust one or more parameters of the grating structure 206 or one or more components of the system (e.g., scanning velocity of the system, or the like).

In a non-limiting example, the frequency of the reference grating time-varying interference signal during scanning may be measured. If the frequency of the reference grating time-varying interference signal has shifted (e.g., does not correspond to the known frequency of the reference grating prior to scanning), then the grating time-varying interference signal may be adjusted based on the shift in frequency of the reference grating time-varying interference signal.

In embodiments, the controller 122 determines an overlay measurement between layers of the overlay target along the measurement direction based on the comparison of the interference signals. For example, the overlay error between sample layers associated with the grating structures in the one or more cells 202 of the overlay target 204 are determined based on the multi-layer time-varying interference signals and the real-time position determined based on the reference grating time-varying interference signal. For instance, the controller 122 may determine an overlay measurement based on the magnitudes and/or phases of the interference signals. U.S. Pat. No. 10,824,079 referenced above and incorporated herein by reference in its entirety generally describes the electric field of diffracted orders in a collection pupil and further provides specific relationships between overlay and measured intensity in the pupil plane. It is contemplated herein that the systems and methods disclosed herein may extend the teachings of U.S. Pat. No. 10,824,079 to time-varying interference signals captured by photodetectors placed in overlap regions between 0 and +/−1 diffraction orders). In particular, it is contemplated herein that overlay on a sample may be proportional to the relative phase shift between the two time-varying interference signals.

Further, the controller 122 may calibrate or otherwise modify the overlay measurement based on known, assumed, or measured features of the sample that may also impact the time-varying interference signals such as, but not limited to, sidewall angles or other sample asymmetries.

The photodetectors 112 may generally include any type of optical detector known in the art suitable for capturing interference signals generated as the sample 104 is translated by the translation stage 116 and/or as one or more illumination beams 108 are scanned by the beam-scanning sub-system 118. For example, the photodetectors 112 may include, but are not limited to, fast photodiodes, photomultipliers, or avalanche photodiodes.

In a general sense, the bandwidth or response time of the photodetectors 112 should be sufficient to resolve the temporal frequency of the interference fringes, which is related to the pitch of the gratings of the grating structure 206 and reference grating structure 208, and the scanning speed along a measurement direction (the direction of periodicity of the grating structure 206 and the reference grating structure 208). For example, in the case of a scan speed along a measurement direction of 10 centimeters per second and a target pitch of 1 micrometer, the interference signals will oscillate at a rate on the order of 100 KHz. In some embodiments, the photodetectors 112 include photodetectors having a bandwidth of at least 200 kHz (Nyquist frequency limit). However, it is to be understood that this value is not a requirement. Rather, the bandwidth of the photodetectors 112, the translation speed along the measurement direction, and the pitch of the grating structures and reference grating structure may be selected together to provide a desired sampling rate of the interference signal.

The one or more processors 124 of the controller 122 may generally include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 124 may include any device configured to execute algorithms and/or instructions (e.g., program instructions stored in memory). In some embodiments, the one or more processors 124 may be embodied as a desktop computer, mainframe computer system, workstation, image computer, parallel processor, networked computer, or any other computer system configured to execute a program configured to operate or operate in conjunction with the overlay metrology system 100, as described throughout the present disclosure. Moreover, different subsystems of the overlay metrology system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 122 may include one or more controllers housed in a common housing or within multiple housings. In this way, any controller or combination of controllers may be separately packaged as a module suitable for integration into metrology overlay metrology system 100. Further, the controller 122 may analyze or otherwise process data received from the photodetectors 112 and feed the data to additional components within the overlay metrology system 100 or external to the overlay metrology system 100.

Further, the memory device 126 may include any storage medium known in the art suitable for storing program instructions executable by the associated one or more processors 124. For example, the memory device 126 may include a non-transitory memory medium. As an additional example, the memory device 126 may include, but is not limited to, a read-only memory, a random-access memory, a magnetic or optical memory device (e.g., disk), a magnetic tape, a solid-state drive and the like. It is further noted that memory device 126 may be housed in a common controller housing with the one or more processors 124.

Referring again to FIG. 1B, various components of the overlay metrology tool 102 are described in greater detail in accordance with one or more embodiments of the present disclosure.

In embodiments, the illumination sub-system 106 includes an illumination source 128 configured to generate at least one illumination beam 108. The illumination from the illumination source 128 may include one or more selected wavelengths of light including, but not limited to, ultraviolet (UV) radiation, visible radiation, or infrared (IR) radiation.

The illumination source 128 may include any type of illumination source suitable for providing at least one illumination beam 108. In some embodiments, the illumination source 128 is a coherent light source. For example, the coherent light source may be a laser source. For instance, the illumination source 128 may include, but is not limited to, one or more narrowband laser sources, a broadband laser source, a supercontinuum laser source, a white light laser source, or the like. In this regard, the illumination source 128 may provide an illumination beam 108 having high coherence (e.g., high spatial coherence and/or temporal coherence). In some embodiments, the illumination source 128 includes a laser-sustained plasma (LSP) source. For example, the illumination source 128 may include, but is not limited to, an LSP lamp, an LSP bulb, or an LSP chamber suitable for containing one or more elements that, when excited by a laser source into a plasma state, may emit broadband illumination.

In embodiments, the illumination sub-system 106 includes one or more optical components suitable for modifying and/or conditioning the illumination beam 108 as well as directing the illumination beam 108 to the sample 104. For example, the illumination sub-system 106 may include one or more illumination lenses 130 (e.g., to collimate the illumination beam 108, to relay an illumination pupil plane 120 and/or an illumination field plane 132, or the like). In some embodiments, the illumination sub-system 106 includes one or more illumination control optics 134 to shape or otherwise control the illumination beam 108. For example, the illumination control optics 134 may include, but are not limited to, one or more apodizers, one or more field stops, one or more pupil stops, one or more polarizers, one or more filters, one or more beam splitters, one or more diffusers, one or more homogenizers, one or more beam shapers, or one or more mirrors (e.g., static mirrors, translatable mirrors, scanning mirrors, or the like).

In embodiments, the overlay metrology tool 102 includes an objective lens 136 to focus the illumination beam 108 onto the sample 104 (e.g., an overlay target with overlay target elements located on two or more layers of the sample 104).

In embodiments, the illumination sub-system 106 illuminates the sample 104 with two or more illumination beams 108. Further, the two or more illumination beams 108 may be, but are not required to be, incident on different portions of the sample 104 (e.g., different cells of an overlay target) within a measurement field of view (e.g., a field of view of the objective lens 136). It is contemplated herein that the two or more illumination beams 108 may be generated using a variety of techniques. In some embodiments, the illumination sub-system 106 includes two or more apertures at an illumination field plane 132. In some embodiments, the illumination sub-system 106 includes one or more beamsplitters to split illumination from the illumination source 128 into the two or more illumination beams 108. In some embodiments, at least one illumination source 128 generates two or more illumination beams 108 directly. In a general sense, each illumination beam 108 may be considered to be a part of a different illumination channel regardless of the technique in which the various illumination beams 108 are generated.

In embodiments, the collection sub-system 110 includes at least two photodetectors 112 (e.g., photodetectors 112a,b) located at a collection pupil plane 114 configured to capture light from the sample 104 (e.g., collected light 138), where the collected light 138 includes at least the 0-order diffraction 306, the −1 order diffraction 308, and the +1 order diffraction 310 as illustrated in FIG. 3B. The collection sub-system 110 may include one or more optical elements suitable for modifying and/or conditioning the collected light 138 from the sample 104. In some embodiments, the collection sub-system 110 includes one or more collection lenses 140 (e.g., to collimate the illumination beam 108, to relay pupil and/or field planes, or the like), which may include, but are not required to include, the objective lens 136. In some embodiments, the collection sub-system 110 includes one or more collection control optics 142 to shape or otherwise control the collected light 138. For example, the collection control optics 142 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the collection sub-system 110 includes two or more collection channels 144, each with a separate pair of photodetectors 112. For example, as illustrated in FIG. 1B, the overlay metrology tool 102 may include one or more beamsplitters 146 arranged to split the collected light 138 into the collection channels 144. Further, the beamsplitters 146 may be polarizing beamsplitters, non-polarizing beamsplitters, or a combination thereof. It is to be understood, however, that the illustration of two collection channels 144 in FIG. 1B is provided solely for illustrative purposes and should not be interpreted as limiting. For example, the collection sub-system 110 may include a single collection channel 144 or multiple collection channels 144.

In embodiments, multiple collection channels 144 are configured to collect light from multiple illumination beams 108 on the sample 104. For example, in the case that an overlay target 204 has one or more cells 202 distributed in a direction different than a scan direction, the overlay metrology tool 102 may simultaneously illuminate the different cells 202 with different illumination beams 108 and simultaneously capture interference signals associated with each illumination beam 108. Additionally, in some embodiments, multiple illumination beams 108 directed to the sample 104 may have different polarizations. In this way, the diffraction orders associated with each of the illumination beams 108 may be separated. For example, polarizing beamsplitters 146 may efficiently separate the diffraction orders associated with the different illumination beams 108. By way of another example, polarizers may be used in one or more collection channels 144 to isolate desired diffraction orders for measurement.

In embodiments, the overlay metrology tool 102 includes a beam-scanning sub-system 118 to position, scan, or modulate positions of one or more illumination beams 108 on the sample 104 during measurement.

The beam-scanning sub-system 118 may include any type or combination of elements suitable for scanning positions of one or more illumination beams 108. In some embodiments, the beam-scanning sub-system 118 includes one or more deflectors suitable for modifying a direction of an illumination beam 108. For example, a deflector may include, but is not limited to, a rotatable mirror (e.g., a mirror with adjustable tip and/or tilt). Further, the rotatable mirror may be actuated using any technique known in the art. For example, the deflector may include, but is not limited to, a galvanometer, a piezo-electric mirror, or a micro-electro-mechanical system (MEMS) device. By way of another example, the beam-scanning sub-system 118 may include an electro-optic modulator, an acousto-optic modulator, or the like.

The deflectors may further be positioned at any suitable location in the overlay metrology tool 102. In some embodiments, one or more deflectors are placed at one or more pupil planes common to both the illumination sub-system 106 and the collection sub-system 110. In this regard, the beam-scanning sub-system 118 may be a pupil-plane beam scanner and the associated deflectors may modify the positions of one or more illumination beams 108 on the sample 104 without impacting positions of diffraction orders in the collection pupil plane 114. Further, a distribution of one or more illumination beams 108 in an illumination field plane 132 may further be stable as the beam-scanning sub-system 118 modifies positions of the one or more illumination beams 108 on the sample 104. Pupil-plane beam scanning is described generally in U.S. Pat. No. 11,300,524, issued on Apr. 12, 2022, which is incorporated by reference in its entirety.

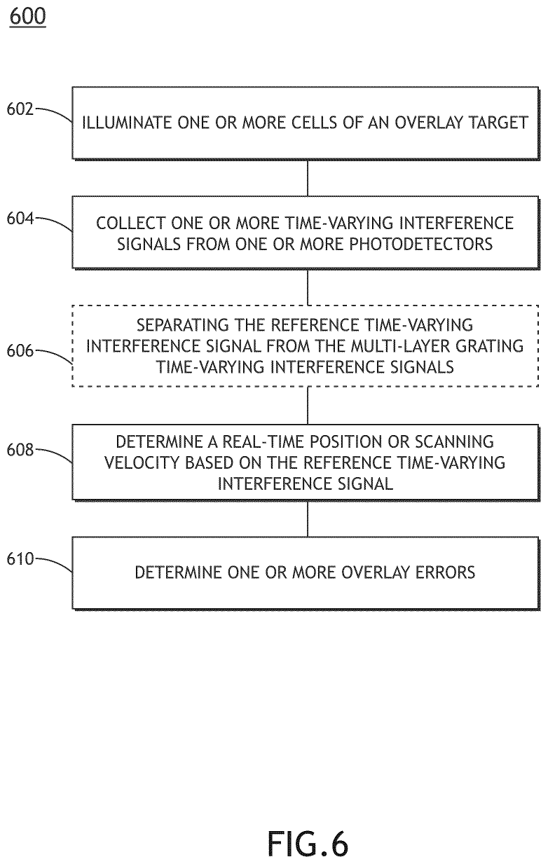

FIG. 6 is a flow diagram illustrating steps performed in a method 600 for scanning overlay metrology of overlay targets, in accordance with one or more embodiments of the present disclosure. Applicant notes that the embodiments and enabling technologies described previously herein in the context of the overlay metrology system 100 should be interpreted to extend to the method 600. It is further noted, however, that the method 600 is not limited to the architecture of the overlay metrology system 100.

In a step 602, one or more cells of an overlay target are illuminated. For example, the one or more cells 202 of the overlay target 204 on the sample 104 are illuminated as the sample 104 is scanned with respect to the illumination, wherein the one or more cells include the grating structures 206 formed from non-overlapping gratings with different pitches.

In a step 604, time-varying interference signals from one or more photodetectors 112a,b may be collected. For example, the time-varying interference signals from the two photodetectors 112a,b placed in regions of the collection pupil associated with overlapping diffraction from the gratings in the grating structures 206. For instance, non-limiting configurations may include, but are not limited to, photodetectors may be placed at locations including exclusively grating diffraction orders, both grating diffraction orders and 0-order diffraction, or only the first-order diffraction from gratings of a grating structure 206.

In an optional step 606, the time-varying interference signals from the one or more photodetectors 112a,b may be separated. For example, the time-varying interference signals associated with the reference grating structure 208 may be separated from the time-varying interference signals associated with the grating structure 206. In one instance, the controller 122 may be configured to separate the respective interference signals using Fourier transform techniques. In another instance, the controller 122 may be configured to separate the respective interference signals using model fitting.

In some embodiments, the interference signals associated with the reference grating structure 208 are spatially separated from the interference signals associated with the grating structure 206. For example, the spatially separated signals may be read using a dedicated diode in the field. In this regard, the controller 122 may receive the spatially separated signals, as discussed further herein.

In a step 608, one of a real-time position or a scanning velocity is determined based on the reference grating time-varying interference signal from the reference grating. For example, in a non-limiting example, the controller 122 may be configured to determine the reference time-varying interference signal based on the separated time-varying interference signals. By way of another example, in a non-limited example, the controller 122 may be configured to receive the reference time-varying interference signal from the dedicated diode.

As previously discussed herein, errors may originate from the stability of the scanning velocity, where the position may be used to improve accuracy and stability of the scanning measurement. It is contemplated that the reference signal may be used to improve accuracy and stability of the system. For example, in a non-limiting example, the frequency of the reference grating time-varying interference signal during scanning may be monitored. In this non-limiting example, if the frequency of the reference grating time-varying interference signal has changed during scanning, the scanning velocity may have changed during scanning. As such, any shift in the frequency of the reference grating time-varying interference signal may be used to adjust the grating time-varying interference signal, such that accuracy and stability of the scanning measurement is improved.

By way of another non-limiting example, the position of the reference grating time-varying interference signal during scanning may be monitored. In this non-limiting example, if the position of the reference grating time-varying interference signal has changed during scanning, the position may have changed during scanning. As such, any shift in the position of the reference grating time-varying interference signal may be used to adjust the grating time-varying interference signal, such that accuracy and stability of the scanning measurement is improved.

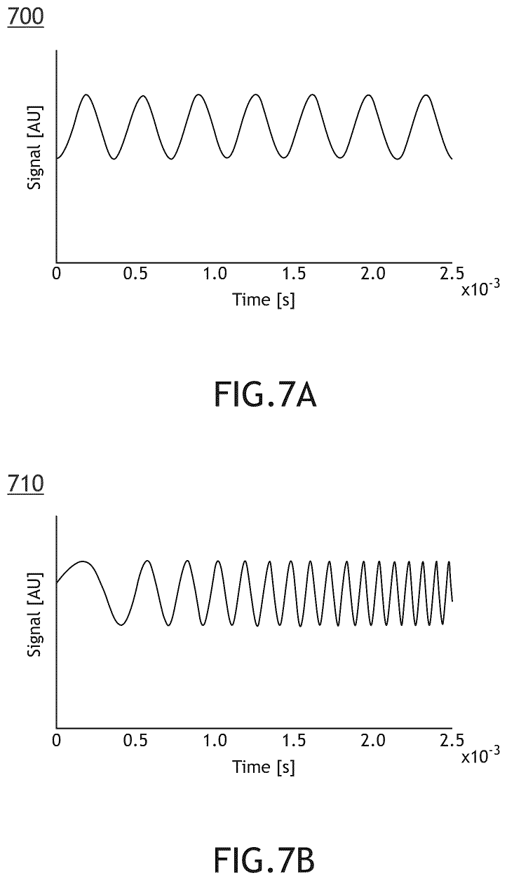

FIG. 7A is a plot 700 depicting measurement signal under constant scanning velocity, in accordance with one or more embodiments of the present disclosure. FIG. 7B is a plot 710 depicting measurement signal under inconstant scanning velocity, in accordance with one or more embodiments of the present disclosure.

When the scanning velocity is constant (e.g., the velocity is stable), as depicted in the plot 700 shown in FIG. 7A, the respective time-varying interference signals of the reference grating 208 may have a constant periodicity. However, when the scanning velocity is not constant (e.g., the velocity is instable), as depicted in the plot 710 shown in FIG. 7B, the frequency and/or phase of the respective time-varying interference signals of the reference grating 208 may not have a constant periodicity. In a non-limiting example, as shown in FIG. 7B, where the scanning velocity is speeding up (or ramping up), the respective time-varying interference signals of the reference grating 208 may reflect such speeding up. As such, the time-varying interference signals of the reference grating 208 may be used to calibrate (or adjust) the time-varying signals of the grating structure 206 when the time-varying interference signals of the reference grating structure 208 are instable (e.g., when the scanning velocity is instable). Put another way, the time-varying interference signals from the reference grating may be used to generate a real-time position and/or scanning velocity measurement of the sample during a scan such that any instabilities in the sample position and/or scanning velocity may be compensated for when providing an overlay measurement. It is contemplated herein that the time-varying interference signals from the reference grating 208 may enable accurate overlay measurements in a wide range of measurement conditions, which may increase throughput. As an illustration, requiring a constant scanning velocity during a measurement (e.g., as depicted in FIG. 7A) would require a relatively long sample scan pattern to allow a translation stage to achieve constant scanning velocity prior to reaching an overlay target of interest. In contrast, the use of time-varying interference signals from a reference grating 208 on the sample captured simultaneously with time-varying interference signals from the grating structure 206 removes this requirement and enables measurements when a translation stage is speeding up (e.g., as depicted in FIG. 7B), slowing down, or otherwise not constant at the location of an overlay target of interest, which may substantially improve measurement throughput.

In embodiments, the phase information of the time-varying interference signals from the grating structure is calibrated (or adjusted) based on the phase information of the time-varying interference signals from the reference grating structure. For example, the phase information of the time-varying inference signals may be extracted from the reference grating structure and used to adjust the phase information of the time-varying interference signals extracted from the grating structure, such that the time-varying interference signals from the grating structure are corrected based on the reference grating structure. In this regard, the real time position and/or scanning velocity may be determined and then the respective time-varying interference signals from the grating structure 206 may be calibrated accordingly.

In a step 610, an overlay error between the one or more sample layers associated with the grating structures may be determined. For example, the overlay error between sample layers associated with the grating structures in the one or more cells 202 of the overlay target 204 are determined based on the multi-layer time-varying interference signals and the real-time position determined based on the reference grating time-varying interference signal. For instance, an overlay error along a direction of periodicity of the grating structures 206 may be proportional to a phase difference between the time-varying interference signals from the two photodetectors. The phase difference may be determined using any technique known in the art including, but not limited to, frequency-domain analysis techniques (e.g., Fast Fourier Transform, or the like) applied to the two time-varying interference signals. Further, in some embodiments, overlay measurements of the sample along a particular measurement direction may be generated based on data from multiple cells of the overlay target with grating structures having periodicity along the particular measurement direction.

In embodiments, the overlay error between the one or more sample layers associated with the grating structures 206 may be determined based on Equations 1, as shown and described by:

$${OVL}_{P - Q} = {X}_{P} - {X}_{Q} \qquad ( 1 )$$

where the position X of the gratings with pitch P and Q are shown and described by Equations 2.1-2.2 below:

$$\begin{matrix}{X}_{P} = \frac{1}{4 π} ( P ( {ϕ}_{P , 1} + {ϕ}_{P , - 1} ) ) & ( 2.1 ) \\ {X}_{Q} = \frac{1}{4 π} ( Q ( {ϕ}_{Q , 1} + {ϕ}_{Q , - 1} ) ) & ( 2.2 )\end{matrix}$$

It is contemplated herein that the method 600 may be applied to a wide variety of overlay target designs suitable for 1D or 2D metrology measurements.

In embodiments, the reference time-varying interference signal may be used as the real-time position of the sample. For example, the reference grating time-varying interference signal may be used to analyze the grating time-varying interference signals from the grating structure 206. In this regard, the reference grating time-varying interference signal may be used as a feedback or feedforward loop to adjust one or more parameters of the grating structure 206 or one or more components of the system (e.g., scanning velocity of the system, or the like).

In embodiments, the method 600 includes simultaneously scanning multiple illumination beams and collecting the associated overlapping diffraction orders for parallel measurements.

In embodiments, the method 600 includes scanning one or more illumination beams along a beam-scan direction different than the stage-scan direction to provide a diagonal or triangle-wave path across the sample. In this regard, cells having grating structures with different directions of periodicity may be efficiently interrogated by a common illumination beam in a measurement swath.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology system comprising:
an illumination sub-system comprising:
an illumination source configured to generate one or more illumination beams; and
one or more illumination optics configured to direct the one or more illumination beams to an overlay target on a sample as the sample is scanned relative to the one or more illumination beams along a scan direction when implementing a metrology recipe,
wherein the overlay target in accordance with the metrology recipe includes one or more cells having a grating structure and a reference grating structure,
wherein the grating structure includes one or more diffraction gratings, wherein the reference grating structure includes a reference grating arranged next to the one or more diffraction gratings of the grating structure, wherein the one or more illumination beams simultaneously interact with the grating structure and the reference grating structure as the sample is scanned relative to the one or more illumination beams, wherein the one or more diffraction gratings and the reference grating are periodic along the scan direction,
wherein the reference grating has one or more known parameters;
a collection sub-system comprising:
two or more photodetectors located in a pupil plane to capture time-varying interference signals associated with diffraction orders of the grating structure and a time-varying interference signal associated with diffraction orders of the reference grating structure in the one or more cells when implementing the metrology recipe; and
a controller communicatively coupled to the two or more photodetectors, the controller including one or more processors configured to execute program instructions causing the one or more processors to:
receive the time-varying interference signals from the two or more photodetectors, the time-varying interference signals including grating signals associated with the grating structures in the one or more cells as the overlay target is scanned in accordance with the metrology recipe and a reference grating signal associated with the reference grating structure in the one or more cells as the overlay target is scanned in accordance with the metrology recipe;
determine at least one of a real-time position or a scanning velocity of the grating structure during the scan based on the reference grating signal from the reference grating; and
determine one or more overlay errors based on the grating signals from the grating structure and the at least one of the real-time position or the scanning velocity of grating structure during the scan determined based on the reference grating signal from the reference grating structure.

2. The overlay metrology system of claim 1, wherein the one or more processors are configured to execute program instructions causing the one or more processors to:
extract phase information associated with the grating signals and the reference grating signal; and
adjust the phase information of the grating signals based on the phase information of the reference grating signal.

3. The overlay metrology system of claim 1, wherein the one or more processors are configured to execute program instructions causing the one or more processors to:
adjust the scanning velocity based on the reference grating time-varying interference signals associated with the reference grating structure.

4. The overlay metrology system of claim 1, wherein the one or more processors are configured to execute program instructions causing the one or more processors to:
separate the reference signal associated with the reference grating structure from the grating signals associated with the grating structures.

5. The overlay metrology system of claim 1, wherein the one or more illumination beams comprises:
a spatially coherent illumination beam.

6. The overlay metrology system of claim 1, wherein the one or more illumination beams comprised one or more elongated beams, wherein the one or more elongated beams are elongated orthogonally in the scan direction, wherein the one or more elongated beams simultaneously interact with the one or more diffraction gratings of the grating structure and the reference grating as the overlay target is scanned.

7. The overlay metrology system of claim 6, wherein the one or more illumination optics are configured to modify the one or more illumination beams to generate the one or more elongated beams.

8. The overlay metrology system of claim 7, wherein the one or more illumination optics comprise one or more apodizers.

9. The overlay metrology system of claim 6, wherein the illumination source is configured to generate the one or more elongated beams.

10. The overlay metrology system of claim 1, wherein the one or more illumination beams comprise one or more separated illumination beams, wherein a first illumination beam of the one or more separated illumination beams interacts with the one or more diffraction gratings of the grating structure and a second illumination beam of the one or more separated illumination beams interacts with the reference grating of the reference grating structure as the overlay target is scanned.

11. The overlay metrology system of claim 10, wherein the one or more illumination optics are configured to separate the one or more illumination beams to generate the one or more separated illumination beams.

12. The overlay metrology system of claim 11, wherein the one or more illumination optics comprise one or more apodizers.

13. The overlay metrology system of claim 1, wherein the one or more diffraction gratings of the grating structure comprises:
a first exposure structure on a first layer of the sample; and
a second exposure structure on a second layer of the sample.

14. The overlay metrology system of claim 13, wherein the first exposure structure and the second exposure structure form a grating-over-grating structure, wherein the first exposure structure overlaps with the second exposure structure.

15. The overlay metrology system of claim 13, wherein the first exposure structure and the second exposure structure form a non-overlapping side-by-side grating structure, wherein the first exposure structure is arranged adjacent to the second exposure structure.

16. The overlay metrology system of claim 1, wherein the one or more known parameters of the reference grating includes a known pitch.

17. The overlay metrology system of claim 16, wherein the known pitch of the reference grating is different from pitches of the one or more diffraction gratings of the grating structure.

18. The overlay metrology system of claim 1, wherein the two or more photodetectors are located in the pupil plane at two or more locations, wherein a first location including a first photodetector includes a location of +1 grating order diffraction associated with grating diffraction from the grating structure and the reference grating structure and 0-order diffraction, wherein a second location including a second photodetector includes a location of −1 grating order diffraction associated with grating diffraction from the grating structure and the reference grating structure and 0-order diffraction.

19. The overlay metrology system of claim 1, wherein the two or more photodetectors are located in the pupil plane at two or more locations, wherein a first location including a first photodetector includes a location of +1 grating order diffraction associated with grating diffraction from the grating structure and the reference grating structure and a portion of illumination split from the generated one or more illumination beams prior to incidence on the sample, wherein a second location including a second photodetector includes a location of −1 grating order diffraction associated with grating diffraction from the grating structure and the reference grating structure and a portion of illumination split from the generated one or more illumination beams prior to incidence on the sample.

20. The overlay metrology system of claim 1, wherein the one or more illumination optics direct the one or more illumination beams to the overlay target at a normal incidence angle.

21. The overlay metrology system of claim 1, further comprising:
a translation stage to translate the sample along the scan direction, wherein the one or more illumination optics direct the illumination beam to the overlay target on the sample as the sample is scanned by the translation stage.

22. The overlay metrology system of claim 1, further comprising:
one or more beam-scanning optics to scan the illumination beam along the scan direction.

23. A method comprising:
receiving time-varying interference signals from two or more photodetectors associated with a grating structure and a reference grating structure in one or more cells as an overlay target is scanned in accordance with a metrology recipe,
wherein the overlay target in accordance with the metrology recipe includes the one or more cells having the grating structure and the reference grating structure, wherein the grating structure includes one or more diffraction gratings, wherein the reference grating structure includes a reference grating arranged next to the one or more diffraction gratings of the grating structure, wherein the one or more illumination beams simultaneously interact with grating structure and the reference grating structure as the sample is scanned relative to the illumination beam, wherein the one or more diffraction gratings and the reference grating are periodic along the scan direction, wherein the reference grating has one or more known parameters,
wherein the time-varying interference signals include grating signals associated with the grating structures in the one or more cells as the overlay target is scanned in accordance with the metrology recipe and a reference grating signal associated with the reference grating structure in the one or more cells as the overlay target is scanned in accordance with the metrology recipe;
determining at least one of a real-time position or a scanning velocity of the grating structure during the scan based on the reference grating signal from the reference grating; and
determining one or more overlay errors based on the grating signals from the grating structure and the real-time position of the grating structure during the scan determined based on the reference grating signal from the reference grating structure.

24. The method of claim 23, further comprising:
extracting phase information associated with the grating signals and the reference grating signal; and
adjusting the phase information of the grating signals based on the phase information of the reference grating signal.

25. The method of claim 23, further comprising:
adjusting the scanning velocity based on the reference grating signals associated with the reference grating structure.

26. The method of claim 23, further comprising:
separating the reference signal associated with the reference grating structure from the grating signals associated with the grating structures.

27. The method of claim 23, wherein the one or more illumination beams comprised one or more elongated beams, wherein the one or more elongated beams are elongated orthogonally in the scan direction, wherein the one or more elongated beams simultaneously interact with the one or more diffraction gratings of the grating structure and the reference grating as the overlay target is scanned.

28. The method of claim 27, wherein the one or more illumination beams comprise one or more separated illumination beams, wherein a first illumination beam of the one or more separated illumination beams interacts with the one or more diffraction gratings of the grating structure and a second illumination beam of the one or more separated illumination beams interacts with the reference grating of the reference grating structure as the overlay target is scanned.

29. The method of claim 23, wherein the one or more known parameters of the reference grating includes a known pitch, wherein the known pitch of the reference grating is different from pitches of the one or more diffraction gratings of the grating structure.

30. An overlay metrology target comprising:
one or more cells having a grating structure and a reference grating structure,
wherein the grating structure includes one or more diffraction gratings,
wherein the reference grating structure includes a reference grating arranged adjacent to the one or more diffraction gratings of the grating structure,
wherein one or more illumination beams are configured to simultaneously interact with grating structure and the reference grating structure as a sample is scanned relative to the one or more illumination beams,
wherein the one or more diffraction gratings and the reference grating are periodic along the scan direction,
wherein the reference grating has one or more known parameters.

31. The overlay metrology target of claim 30, wherein the one or more diffraction gratings of the grating structure comprise:
a first exposure structure on a first layer of the sample; and
a second exposure structure on a second layer of the sample.

32. The overlay metrology target of claim 31, wherein the first exposure structure and the second exposure structure form a grating-over-grating structure, wherein the first exposure structure overlaps with the second exposure structure.

33. The overlay metrology target of claim 31, wherein the first exposure structure and the second exposure structure form a non-overlapping side-by-side grating structure, wherein the first exposure structure is arranged adjacent to the second exposure structure.

34. The overlay metrology target of claim 30, wherein the one or more known parameters of the reference grating include a known pitch.

35. The overlay metrology target of claim 34, wherein the known pitch of the reference grating is different from pitches of the one or more diffraction gratings of the grating structure.
